(19) United States
(12) Patent Application Publication
(10) Pub. No.: US 2026/0198331 A1
(43) Pub. Date: Jul. 9, 2026

(54) Die Labelling for Semiconductor Die

(71) Applicant: Wolfspeed, Inc., Durham, NC (US)

(72) Inventors: Chandrasekhar Sarma, Portland, OR (US); William Donald Hughes, Utica, NY (US); Evan Robinson, New Hartford, NY (US)

(21) Appl. No.: 19/009,387

(22) Filed: Jan. 3, 2025

(51) Int. Cl. H01L 23/544; H10D 62/832

(52) U.S. Cl. CPC H10W 46/00; H10D 62/8325; H10W 46/103; H10W 46/401; H10W 46/603

(57) ABSTRACT

One example embodiment is directed to a semiconductor die. The semiconductor die includes a semiconductor structure, the semiconductor structure including a portion of a semiconductor wafer. The semiconductor die includes a die label, the die label indicative of a fabrication position of the semiconductor die on the semiconductor wafer. The die label has a first portion identifying a location of the semiconductor die within a reticle field and a second portion identifying a location of the reticle field on the semiconductor wafer. The semiconductor wafer includes two or more reticle fields.

### FIELD

The present disclosure relates generally to semiconductor device fabrication, and more particularly to die labeling for semiconductor die fabricated on a semiconductor wafer, such as a silicon carbide semiconductor wafer.

### BACKGROUND

Semiconductor devices, such as processors, memory devices, transistors, etc., may be fabricated from one or more semiconductor die formed on a semiconductor wafer, such as a silicon semiconductor wafer. Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”), and other devices. Example semiconductor devices may be diodes, such as Schottky diodes or other devices. These semiconductor devices may be fabricated from wide bandgap semiconductor materials, such as silicon carbide (“SiC”) and/or Group III nitride-based (e.g., gallium nitride (“GaN”)) semiconductor materials.

### SUMMARY

Aspects and advantages of embodiments of the present disclosure will be set forth in part in the following description, or can be learned from the description, or can be learned through practice of the embodiments.

One example embodiment is directed to a semiconductor die. The semiconductor die includes a semiconductor structure, the semiconductor structure including a portion of a semiconductor wafer. The semiconductor die includes a die label, the die label indicative of a fabrication position of the semiconductor die on the semiconductor wafer. The die label has a first portion identifying a location of the semiconductor die within a reticle field and a second portion identifying a location of the reticle field on the semiconductor wafer. The semiconductor wafer includes two or more reticle fields.

One example embodiment is directed to a method of providing a die label as part of each of a plurality of semiconductor die. The method includes, for each reticle field of a plurality of reticle fields for a semiconductor wafer, exposing the semiconductor wafer with a first mask. The method includes, for each reticle field of the plurality of reticle fields, exposing the semiconductor wafer with a second mask at an offset relative to the first mask to provide an indicator on each of a plurality of semiconductor die within the reticle field, the indicator providing a position of the reticle field on the semiconductor wafer.

One example embodiment is directed to a semiconductor wafer. The semiconductor wafer includes a plurality of semiconductor die, the plurality of semiconductor die arranged in a plurality of reticle fields on the semiconductor wafer, each reticle field associated with an exposure of a mask on the semiconductor wafer. Each of the plurality of semiconductor die includes a unique die label, and the unique die label includes an indicator indicative of a position of one of the plurality of reticle fields on the semiconductor wafer.

One example embodiment is directed to a method of providing a die label as part of each of a plurality of semiconductor die on a semiconductor wafer. The method includes exposing a first reticle field of a plurality of reticle fields with a mask at a first dosage. The method includes exposing a second reticle field of the plurality of reticle fields with a mask at a second dosage, the second dosage being different from the first dosage to provide an indicator on each of a plurality of semiconductor die within the reticle field, the indicator providing a position of the reticle field on the semiconductor wafer.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1A depicts an example semiconductor wafer having a plurality of reticle fields according to example embodiments of the present disclosure.

FIG. 1B depicts a plurality of semiconductor die in an example reticle field according to example embodiments of the present disclosure.

FIG. 2 depicts an example die label according to example embodiments of the present disclosure;

FIGS. 3A and 3B depict aspects of an example offset overlay mask method for providing an offset overlay mask defined die label according to example embodiments of the present disclosure;

FIGS. 4A, 4B, 4C, and 4D depict aspects of an example offset overlay mask method for providing an offset overlay mask defined die label according to example embodiments of the present disclosure;

FIGS. 5A, 5B, 5C, and 5D depict aspects of an example offset overlay mask method for providing an offset overlay mask defined die label according to example embodiments of the present disclosure;

FIG. 6 depicts example offset overlay mask defined indicators for a plurality of different reticle fields according to example embodiments of the present disclosure;

FIG. 7 depicts example offset overlay mask defined indicators for a plurality of different reticle fields according to example embodiments of the present disclosure;

FIG. 8 depicts a flow chart of an example method according to example embodiments of the present disclosure.

FIG. 9 depicts a flow chart of an example method according to example embodiments of the present disclosure.

FIGS. 10A and 10B depict example adjusted dosage defined indicators for a plurality of different reticle fields according to example embodiments of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Semiconductor device packages (e.g., discrete semiconductor device packages and power modules) have been developed that include a semiconductor die, such as a metal-oxide-semiconductor field-effect transistor (MOSFET), a Schottky diode, and/or a high electron mobility transistor (HEMT) device. Semiconductor device packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Semiconductor device packages with Schottky diodes and/or HEMT devices may be employed in many of the same high-performance power applications described above for MOSFETs, sometimes in systems that also include discrete power packages of MOSFETs.

Power semiconductor device packages may include one or more semiconductor die having at least one semiconductor structure, such as a power semiconductor device. In some examples, power semiconductor devices may include a wide bandgap semiconductor material, such as silicon carbide (SiC) semiconductor materials and/or Group III nitride-based (e.g., gallium nitride (GaN)) semiconductor materials. For instance, in some examples, the one or more semiconductor die may include, e.g., wide bandgap semiconductor devices, silicon carbide-based semiconductor devices (e.g., MOSFETs, Schottky diodes), Group III nitride-based semiconductor devices (e.g., HEMT devices), and the like.

Aspects of the present disclosure are discussed with reference to semiconductor die having a wide bandgap material used in power semiconductor device applications for purposes of illustration and discussion. Those of ordinary skill in the art, using the disclosures provided herein, will understand that the technology described herein may be used with any type of semiconductor die or semiconductor wafer, such as a silicon semiconductor wafer, gallium arsenide semiconductor wafer, or other semiconductor wafer, without deviating from the scope of the present disclosure.

As used herein, a “wide bandgap semiconductor material” refers to a semiconductor material having a band gap greater than about 1.40 eV. Aspects of the present disclosure are discussed herein with reference to silicon carbide-based semiconductor structures/layers as wide bandgap semiconductor structures/layers for purposes of illustration and discussion. Those having ordinary skill in the art, using the disclosures provided herein, will understand that any suitable semiconductor material, such as other wide bandgap semiconductor materials, may be used without deviating from the scope of the present disclosure. By way of non-limiting example, example wide bandgap semiconductor materials include silicon carbide and/or Group III-nitrides.

In some examples, power semiconductor devices may include lateral structures (e.g., lateral semiconductor device units) and/or vertical structures (e.g., vertical semiconductor device units). In a power semiconductor device having a lateral structure, the terminals of the power semiconductor device (e.g., drain terminal, source terminal, gate terminal for a power MOSFET device) are on the same major side (e.g., top side, bottom side) of a semiconductor structure. In contrast, in a power semiconductor device having a vertical structure, at least one terminal is provided on each major side of the semiconductor structure. In other words, each terminal in a lateral semiconductor structure is coplanar, while the terminals in a vertical semiconductor structure are non-coplanar. As used herein, a “semiconductor structure” refers to a structure having one or more semiconductor layers, such as semiconductor substrates and/or semiconductor epitaxial layers. The semiconductor structure may include one or more other materials on the one or more semiconductor layers, such as metallization, oxide (e.g., field oxide, isolation oxide, gate oxide), passivation layers (e.g., polyimide, BPSG), dielectric materials, or other materials.

Semiconductor devices may be fabricated by performing fabrication processes on a semiconductor wafer. A semiconductor wafer is a thin, disc-shaped sheet of semiconductor material (e.g., silicon (Si), SiC, GaN, etc.) that may serve as the foundation for manufacturing semiconductor devices, such as integrated circuits (ICs) and/or other electronic components. In some examples, semiconductor wafers may include one or more epitaxial layers formed on a substrate. As used herein, an “epitaxial layer” is a single-crystal semiconductor layer grown on top of a substrate using a process called “epitaxial growth” and/or “epitaxy.” The epitaxial layer may be deposited atom-by-atom and may adopt the crystal structure of the underlying substrate. Furthermore, a “substrate” refers to a solid semiconductor material upon which epitaxial layers are formed. A substrate may be a homogenous material, such as silicon, silicon carbide and/or sapphire and may provide mechanical support for the formation of epitaxial layers. In some examples, substrates may be provided as a semiconductor wafer on which various other layers and structures are formed. By way of non-limiting example, an example epitaxial layer may have a thickness in a range of, for instance, about 0.2 microns (μm) to about 200 microns (μm), and an example substrate may have a thickness in a range of, for instance, about 0.5 microns (μm) to about 1000 microns (μm) or greater.

A power semiconductor device (e.g., MOSFET, JFETs, Schottky diode, HEMT device, etc.) may be fabricated on a silicon carbide-based semiconductor wafer, which may serve as a substrate for the power semiconductor device. For instance, a plurality of “unit cell” structures (hereinafter “semiconductor device cells”) may be formed in the epitaxial layers. Each of the plurality of semiconductor device cells may include a semiconductor structure such as, for instance, a transistor or other device. In some examples, a large number (e.g., hundreds, thousands, etc.) of these semiconductor device cells may together form a semiconductor device unit, such as a lateral semiconductor device unit and/or a vertical semiconductor device unit. Metal layer structures may be formed on a side of the semiconductor structures of each of the plurality of the semiconductor device cells to form one or more electrodes for the lateral semiconductor device unit (e.g., gate contact, source contact, drain contact).

The semiconductor wafer may be subjected to wafer-level processing and may be singulated to form individual semiconductor die for use in a semiconductor device package, such as a discrete semiconductor device package and/or a power module. More particularly, the semiconductor wafer may include one or more scribe lines between each of the plurality of lateral semiconductor device units. The semiconductor wafer may then be cut and/or diced along the one or more scribe lines between the plurality of lateral semiconductor device units, such that each individual cut piece becomes a semiconductor die that is later packaged in a semiconductor device package (e.g., discrete semiconductor device package, power module).

Aspects of the present disclosure are directed to providing die labels on semiconductor die. Die labels may provide a unique identifier on the individual semiconductor die fabricated from a semiconductor wafer. Die labels may be utilized to optimize or enhance semiconductor fabrication processes and ensure quality.

The small dimensions of a semiconductor die present challenges when providing uniquely identifying reference marks and structures (e.g., a die label) to each semiconductor die on a semiconductor wafer. Equipment and/or process constraints may inhibit photolithography processes with a stepping and scanning mechanism (e.g., a 5× or 4× reduction stepper and/or scanner) from providing uniquely identifiable reference marks (e.g., die labels) to semiconductor die within a semiconductor wafer. For instance, a reduction stepper or scanner lithography tool (e.g., a 5× or 4× reduction stepper) will use the same mask to produce a plurality of reticle fields on a semiconductor wafer. The same mask will be unable to provide unique identifiers for semiconductor die across a plurality of different reticle fields. As used herein, a reticle field refers to the portion of the semiconductor wafer that is exposed using a mask during one step or scan in a photolithography process.

There is significant cost associated with overcoming equipment constraints through modifications of the tool used to provide uniquely identifiable reference marks (e.g., die labels) to die on an entire semiconductor wafer (e.g., for a 1× exposure). This may impact the efficiency of production processes, increase production time, and require significant process development to integrate. As such, a modification of photolithography masking and printing processes using a stepper or scanner (e.g. 5× or 4× stepper) to apply uniquely identifiable reference marks (e.g., die labels) to die within a semiconductor wafer is desired.

Stepping and/or scanning photolithography processes, in general, transfer patterns from a mask, or reticle, onto a photoresist layer provided on at least a portion of the semiconductor wafer through electromagnetic radiation exposure. The portion of the semiconductor wafer that is exposed is referred to as a reticle field. After exposure, the portion of the semiconductor wafer to be patterned is “stepped” or precisely moved and aligned with a mask such that a different portion of the photoresist layer provided on the semiconductor wafer is subjected to photomask patterning. This “step and expose” process may be repeated such that the semiconductor wafer surface (e.g., the photoresist layer) has a photoresist pattern transferred across a majority of the semiconductor wafer surface in a plurality of different reticle fields. The semiconductor wafer may then undergo development, which removes either the exposed photoresist or the unexposed photoresist. Further processing on the wafer may be performed to deposit or remove (e.g., etch) material from the semiconductor wafer.

By applying successive mask patterns, it may be possible to impart uniquely identifiable reference marks (e.g., die labels) to die within a semiconductor wafer during a step and/or scan photolithography process. Aspects of the present disclosure are directed toward a semiconductor die that includes a unique die label identifying both a location of semiconductor die within a particular reticle field and a location of the reticle field on the semiconductor wafer. The semiconductor die may include a semiconductor structure. The semiconductor structure may include a portion of a semiconductor wafer. The semiconductor die may include a die label. The die label may be indicative of a fabrication position of the semiconductor die on the semiconductor wafer. The die label may have a first portion identifying a location of the semiconductor die within a reticle field and a second portion identifying a location of the reticle field on the semiconductor wafer including two or more reticle fields.

In some examples, the first portion may include a row identifier and a column identifier to identify the location of the semiconductor die within the reticle field. In some examples, the row identifier or the column identifier may include an alphanumeric character. In some examples, the second portion may provide an indicator (e.g., visual indicator) of the location of the reticle field on the semiconductor wafer. In some examples, the indicator or identifier is not an alphanumeric character but may be a combination of unique structures.

In some examples, the indicator is an offset overlay mask defined indicator. An offset overlay mask defined indicator may be provided by overlaying a first mask relative to a second mask. During exposure and stepping of the masks across a semiconductor wafer to provide a plurality of reticle fields, the second mask may be offset relative to the first mask such that the second mask is at a unique position relative to the first mask in each different reticle field. In this way, a unique die label may be provided on each individual semiconductor die on the semiconductor wafer using a stepped photolithography process.

In some examples, the first mask is different from the second mask. In some examples, the second mask is the same mask structure as the first mask. For instance, after a first exposure of the first mask, the first mask may be reused as the second mask for a second exposure. In some examples, the first mask may be reused as the second mask with portions of the mask bladed out, blocked, or removed. During the second exposure when the first mask is being reused as the second mask, the position of the mask may be offset to provide an indicator indicative of the position of the reticle field. The offset may be different for each reticle field. In some examples, the indicator may include an overlay box-in-box structure. In some examples, the indicator may include a two-dimensional grid. In some examples, the indicator may be indicative of a total number of reticle fields on the semiconductor substrate. In some examples, the visual indicator may include one or more one dimensional grids. In some examples, the indicator may include one or more lines. A variety of different types of indicators may be used to identify a reticle field position on a semiconductor wafer without deviating from the scope of the present disclosure. In some examples, the second portion identifying the location of the reticle field on the semiconductor wafer may not include an alphanumeric character.

In some examples, the indicator may include an adjusted dosage defined indicator. Dosage of radiation during exposure may affect dimensions of features transferred to semiconductor die on a semiconductor wafer. By making the dosage of radiation exposure of each reticle field different, the size of a feature (e.g., linewidth, number of lines, spacing between lines) on an indicator associated with each reticle field may also be different. In this way, the adjusted dosage defined indicator may provide a location of the reticle field on the semiconductor wafer.

As an example, an indicator for a first reticle field may have a first spacing between lines. An indicator for a second reticle field may have a second spacing between lines. The first spacing may be different than the second spacing. The difference in spacing may be provided by adjusting dosage of radiation exposure for the second reticle field relative to the first reticle field.

In some examples, a reticle field may be associated with a plurality of semiconductor die arranged in a semiconductor die grid. In some examples, the reticle field may be associated with sixteen semiconductor die arranged in a 4×4 semiconductor die grid or other matrix of m x n rows and columns of semiconductor die.

In some examples, the die label may include a material provided on the semiconductor wafer. The die label may be in one or more of a dielectric layer (e.g., polyimide), metallization layer, semiconductor structure, or other material provided as part of the semiconductor die. In some examples, the die label may be defined by etched material from the semiconductor die.

In some examples, different portions of the die label may be on different layers/materials on the semiconductor die. For a portion the die label (e.g., a first portion of the die label) may be on a first layer/material on the semiconductor die 110 and another portion (e.g., a second portion of the die label) may be on a different layer/material on the semiconductor die.

In some examples, the semiconductor wafer may be a wide bandgap semiconductor. In some examples, the semiconductor substrate may be silicon carbide. In some examples, the semiconductor die may include one or more of a silicon carbide-based MOSFET, silicon carbide-based Schottky diode, or silicon carbide-based IGBT. However, as discussed above, the semiconductor wafer may also be a silicon semiconductor wafer or other semiconductor material (e.g., GaAs). The semiconductor die may include, for instance, processors, memory devices, etc. without deviating from the scope of the present disclosure.

Another example aspect of the present disclosure is directed toward a method of providing a die label as part of each of a plurality of semiconductor die. The method may include, for each reticle field of a plurality of reticle fields for a semiconductor wafer, exposing the semiconductor wafer with a first mask. The method may include, for each reticle field of the plurality of reticle fields, exposing the semiconductor wafer with a second mask at an offset relative to the first mask to provide an indicator on each of a plurality of semiconductor die within the reticle field. The indicator may provide a position of the reticle field on the semiconductor wafer.

In some examples, the offset may be different for each reticle field of the plurality of reticle fields. In some examples, the offset may include a first offset in a first dimension and a second offset in a second dimension. In some examples, the first mask may include a first pattern associated with a die label. The first pattern includes a first portion identifying a location of each semiconductor die within one reticle field of the plurality of reticle fields. In some examples, the first portion may include a row identifier and a column identifier to identify the location of the semiconductor die within the reticle. In some examples, the row identifier or the column identifier may include an alphanumeric character. In some examples, the second mask may include a second pattern associated with a die label. The second pattern may include a second portion identifying a position of the reticle field on the semiconductor wafer. In some examples, the second pattern may be an overlay pattern relative to the first mask.

In some examples, the first mask is different from the second mask. In some examples, the second mask is the same mask as the first mask. For instance, the first mask may be reused as the second mask. In some examples, the first mask may be reused as the second mask with portions of the mask bladed out, blocked, or removed such that the mask has a portion at a unique position in each different reticle field.

In some examples, a method may include exposing a first reticle field of a plurality of reticle fields with a mask at a first dosage. The method may include exposing a second reticle field of the plurality of reticle fields with a mask at a second dosage. The second dosage is different from the first dosage to provide an indicator on each of a plurality of semiconductor die within the reticle field. The indicator providing a position of the reticle field on the semiconductor wafer.

Another example aspect of the present disclosure is directed toward a semiconductor wafer. The semiconductor wafer includes a plurality of semiconductor die. The plurality of semiconductor die may be arranged in a plurality of reticle fields on the semiconductor wafer. Each reticle field may be associated with an exposure of a mask on the semiconductor wafer. Each of the plurality of semiconductor die may include a unique die label. The unique die label may include an indicator indicative of a position of one of the plurality of reticle fields on the semiconductor wafer.

Aspects of the present disclosure provide technical effects and benefits. For instance, die labels may provide a unique identifier on the individual component (e.g., a chip) fabricated from a semiconductor wafer, which may be utilized to optimize semiconductor fabrication processes and ensure quality. For instance, a die label may allow tracking of die that do not conform to quality requirements as subsequent fabrication operations are conducted on the die. Subsequent fabrication processes may be tuned such that non-conforming die are brought to conformity, or non-conforming die may be identified and removed prior to subsequent fabrication processes. Providing a unique identifier (e.g., die label) through a photolithography process impacts fabrication (e.g., process development, processing time, cost, material waste, etc.) to a lesser extent when a photolithography process is standard in a fabrication process. A sequence of mask patterns imparting uniquely identifiable reference marks (e.g., die labels) may provide a visual indicator of where a die is located with respect to another die, or on the semiconductor wafer in general. Die labeling allows die traceability for root cause analysis, quality, and statistical process control (SPC).

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

In the drawings and specification, there have been disclosed typical embodiments and, although specific terms are employed, they are used in a generic and descriptive sense only and not for purposes of limitation of the scope set forth in the following claims.

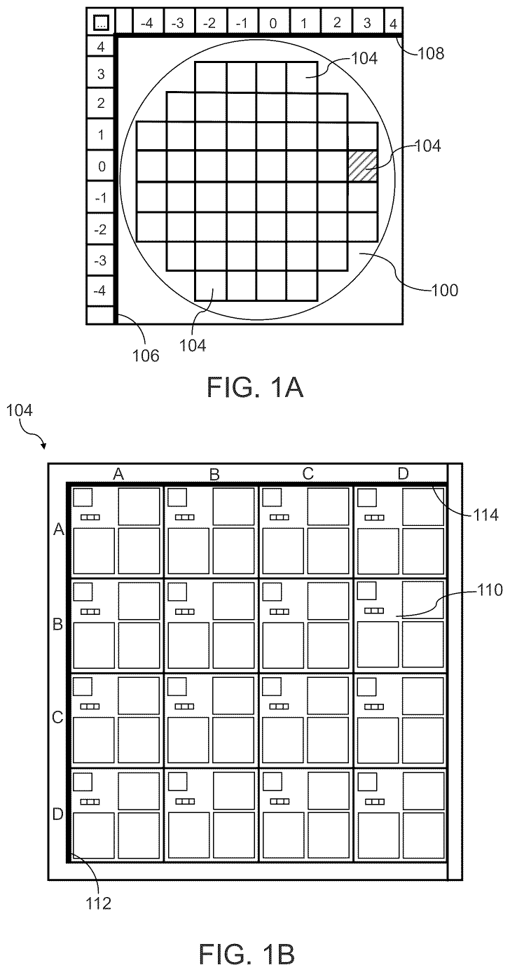

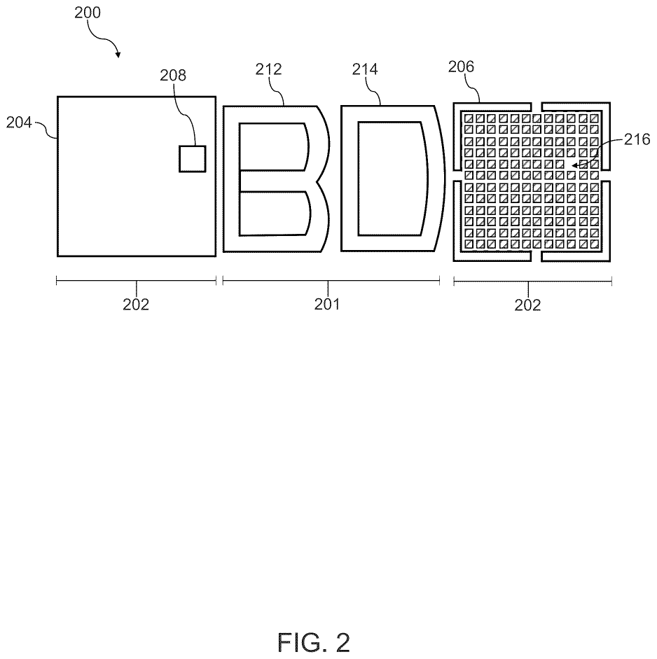

FIG. 1A depicts a top view of an example semiconductor wafer 100 according to example embodiments of the present disclosure. The semiconductor wafer 100 may be a silicon semiconductor wafer. In some embodiments, the semiconductor wafer 100 is a wide bandgap semiconductor wafer and includes, for instance, a wide bandgap semiconductor, such as silicon carbide. Structures in the figures are represented for illustrative purposes and the illustration is not meant to represent features to physical scale.

The semiconductor wafer 100 may include a plurality of reticle fields 104 formed during a stepped photolithography process. The plurality of reticle fields 104 may include a photolithography pattern transferred to the wafer 100 by a photolithography process. Each reticle field 104 may be at a position on the wafer 100. The plurality of reticle fields 104 on the semiconductor wafer 100 may be arranged in a two-dimensional grid. The location of each reticle field 104 on the semiconductor wafer 100 may be represented, for instance, by a column component 106 and a row component 108. For instance, the reticle field 104 that is shaded may be at a position 0, 3 on the wafer with the row component 108 first, and the column component 106 second.

As depicted in FIG. 1B, each reticle field 104 may include an array or grid of semiconductor die 110. Each semiconductor die 110 may include a semiconductor structure. When singulated, each semiconductor die may include a semiconductor structure that is a portion of the semiconductor wafer 100. The semiconductor die 110 may be, for instance, a MOSFET, IGBT, Schottky diode, or other semiconductor device. A 4×4 array of the semiconductor die 110 is depicted in FIG. 1B for the purposes of illustration and discussion. However, the reticle field 104 may include any number of semiconductor die without deviating from the scope of the present disclosure, such as four semiconductor die, nine semiconductor die, twenty five semiconductor die, thirty semiconductor die, etc. The reticle field 104 may also take any suitable shape, such as a square, rectangle, etc.

The location of a semiconductor die 110 within a reticle field 104 may also be represented, for instance, by a row component 112 and a column component 114. The combination of the row component 112 and the column component 114 may denote the fabrication position of the semiconductor die 110 within the reticle field 104. For instance, the semiconductor die 110 that is labeled with the reference character 110 may be at position BD within the reticle field 104, with the row component 112 first and the column component 114 second.

According to example aspects of the present disclosure, each semiconductor die 110 on the semiconductor wafer 100 may include a unique die label 200 that includes a first portion providing a position of the semiconductor die 110 within a reticle field 104 and a second portion providing a position of the reticle field 104 on the semiconductor wafer 100. The unique die label may include a material provided on the semiconductor die 110, such as metallization, semiconductor, oxide (e.g., field oxide, isolation oxide, gate oxide), passivation layers (e.g., polyimide, BPSG), dielectric materials, or other materials. In some examples, the die label 200 may be provided by material removed or etched from the semiconductor die (e.g., etched polyimide, etched metal, etched semiconductor, etched oxide, etched passivation, etc.). In some examples, the die label may be across different layers/materials on the semiconductor die 110. For a portion the die label 200 may be on a first layer/material on the semiconductor die 110 and another portion of the die label 200 may be on a different layer/material on the semiconductor die 110.

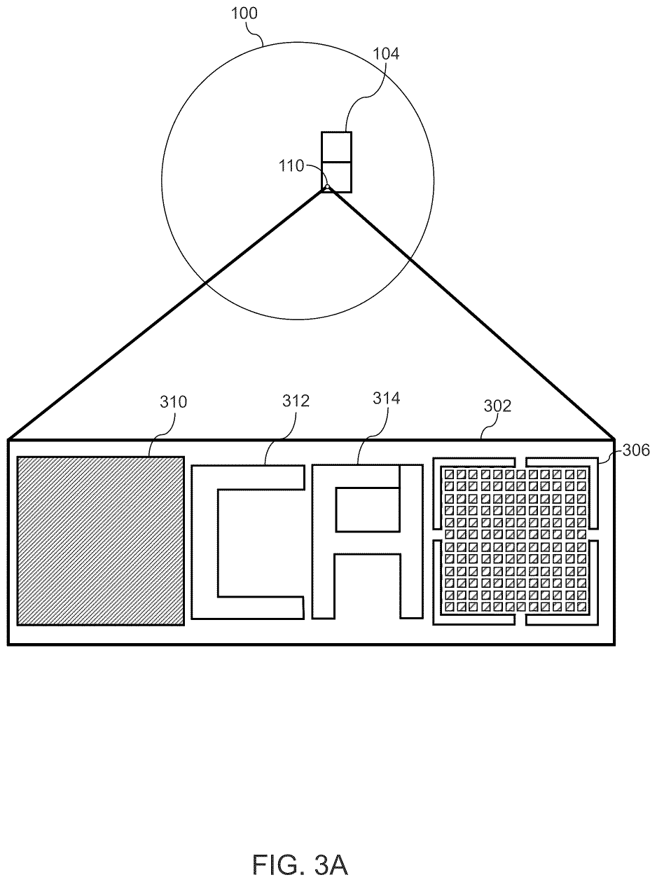

FIG. 2 depicts an example die label 200 that may be on a semiconductor die according to example embodiments of the present disclosure. The die label 200 includes a first portion 201 and a second portion 202. The first portion 201 of the die label 200 may be indicative of a position of a semiconductor die within a reticle field. For instance, the first portion 201 may include a row identifier 212 and a column identifier 214 identifying the row and column of a semiconductor die within a reticle field. The row identifier 212 and the column identifier 214 are alphanumeric characters. However, any suitable character or other indicator or graphic may be used without deviating from the scope of the present disclosure.

The second portion 202 of the die label 200 may include one or more indicators, such as a first indicator 204 and a second indicator 206. Each of the one or more indicators may provide or represent a position of the reticle field on the semiconductor wafer. In this way, each die label provides a unique position of the semiconductor die on a semiconductor wafer. The die label 200 of FIG. 2 includes two indicators providing a position of the reticle field on the semiconductor wafer. However, the second portion may include any number of indicators, such as a single indicator, three indicators, four indicators, etc.

The first indicator 204 may include an overlay box-in-box structure. The overlay box-in-box structure may include a first box 208 that represents the location of the reticle field and a second box 210 that represents the surface of the semiconductor wafer. The position of the first box 208 relative to the second box 210 provides a visual indicator of the location of the reticle field on the semiconductor wafer. More particularly, a spatial orientation of the first box 208 on the first box 210 provides a visual indicator of the position of the reticle field on the wafer.

The indicator 206 may include a two-dimensional grid (e.g., a 12×12 grid). The two-dimensional grid includes a square or other shape representing the location of each reticle field on the semiconductor wafer. In this way, the indicator 206 may provide a representation of the total number of reticle fields on the semiconductor wafer. As depicted in FIG. 2, a cleared square 216, or a portion of the two-dimensional grid of squares that is absent, removed, or otherwise altered may correspond to the position of a specific reticle field relative to the plurality of reticle fields on the semiconductor wafer. In this way, the indicator 206 may provide a visual indicator providing a position of the reticle field on the semiconductor wafer.

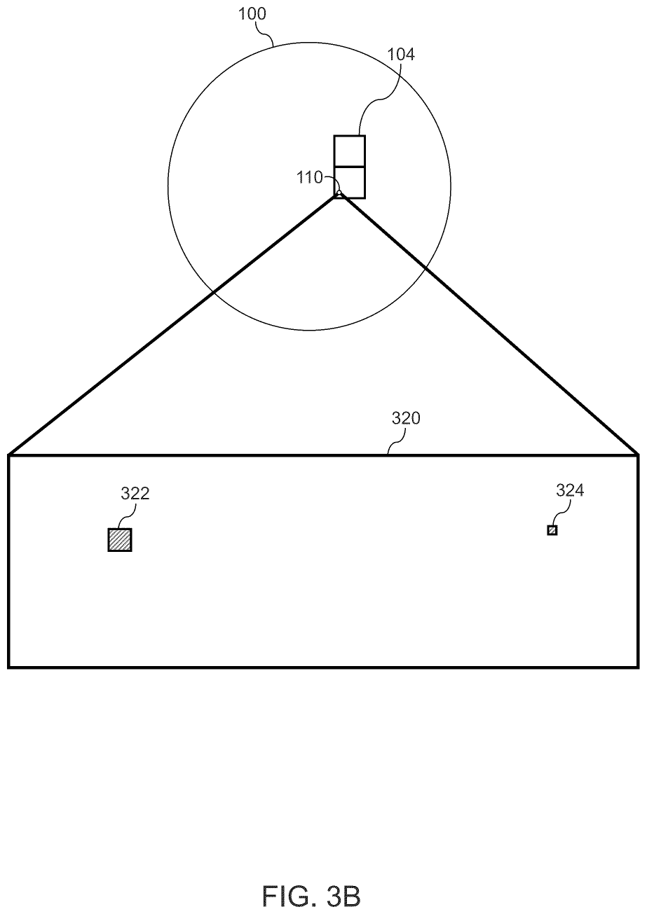

FIGS. 3A and 3B depict an example method of producing an offset overlay defined mask die label according to example embodiments of the present disclosure. FIG. 3A depicts providing, for each reticle field in a plurality of reticle fields 104 for the semiconductor wafer 100, a first mask 302. A portion of the first mask 302 associated with a die label is illustrated in FIG. 3A. The first mask 302 includes a pattern configured to provide the first portion 201 of the die label 200 of FIG. 2 identifying the location of a semiconductor die within a reticle field, including a pattern associated with a row identifier 312 and a column identifier 314. When exposed and processed, the row identifier 312 may provide the row identifier 212 of the die label 200 of FIG. 2. The column identifier 314 may provide the column identifier 214 of the die label 200 of FIG. 2.

The first mask 302 may also include, for instance, a pattern associated with the second box 310 and a pattern associated with the two-dimensional grid 306. When exposed and processed, the pattern associated with the second box 310 may provide the second box 210 of the overlay box-in-box structure of the die label 200 of FIG. 2. When exposed and processed, the pattern associated with the two-dimensional grid 306 may provide the two-dimensional grid of the die label 200 of FIG. 2.

FIG. 3B depicts providing, for each reticle field in a plurality of reticle fields for the semiconductor wafer 100, a second mask 320 to provide an indicator on the die label 200 that provides a position of the reticle field on the semiconductor wafer. More particularly, the second mask 320 may include a pattern associated with a first overlay structure 322 and a pattern associated with a second overlay structure 324. When exposed and processed, the first overlay structure 322 may provide the first box 208 of the overlay box-in-box structure in the die label 200 of FIG. 2. When exposed and processed, the second overlay structure 324 may clear, mark, or alter the square of the two-dimensional grid in the die label 200 of FIG. 2.

The mask 320 is depicted as having two overlay structures, each corresponding to one of the two indicators 204 and 206 of FIG. 2. However, two overlay structures are not required. For instance, for die labels with only a single indicator, only a single overlay structure may be required.

According to example aspects of the present disclosure, the second mask 320 is provided at an offset relative to the first mask 302 to provide a position of the reticle field on the semiconductor wafer. In some examples, the offset of the second mask 320 relative to the first mask 302 is different for each reticle field of the plurality of reticle fields. For instance, the offset of the second mask may be altered in a primarily vertical direction, a primarily horizontal direction, or in both a vertical direction and a horizontal direction so that the offset may include a first offset in a first dimension and a second offset in a second dimension. As described below, moving the second mask 320 with an offset relative to the first mask 302 in a stepped exposure process alters the die label for each reticle field such that the die label may provide a position of the reticle field relative to the semiconductor wafer according to example aspects of the present disclosure.

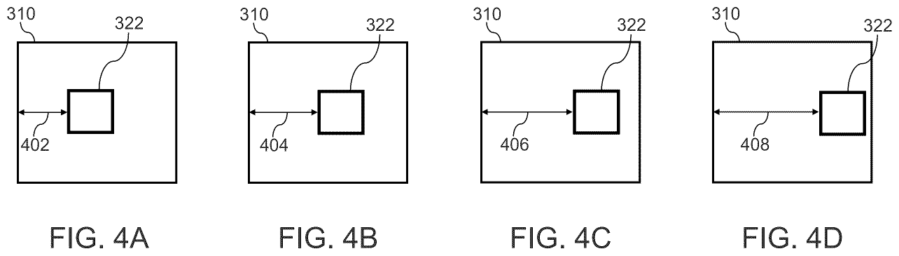

One example of implementing an offset with the second mask 320 is described with reference to FIGS. 4A-4D. For instance, FIG. 4A illustrates a position of the first overlay structure 322 of the second mask 320 relative to the pattern associated with the second box 310 of the first mask 302 for a first reticle field according to examples of the present disclosure. The first overlay structure 322 of the second mask 320 may be positioned such that there is a first distance 402 between an edge of the first overlay structure 322 relative to an edge of the pattern associated with the second box 310.

FIG. 4B illustrates the stepping of the masks to a second reticle field immediately to the right of the first reticle field of FIG. 4A. As shown, the second mask 320 is moved with an offset relative to the first mask 302 such that the first overlay structure 322 is positioned further to the right relative to the pattern associated with the second box 310 of the first mask 302. The first overlay structure 322 of the second mask 320 may be positioned such that there is a second distance 404 between an edge of the first overlay structure 322 relative to an edge of the pattern associated with the second box 310. The second distance 404 is greater than the first distance 402. In this way, when exposed and processed, the first overlay structure 322 will shift the position of the first box 208 relative to the second box 210 of the die label 200 of FIG. 2 in the second reticle field, providing a position of the second reticle field on the semiconductor wafer.

FIG. 4C illustrates the stepping of the masks to a third reticle field immediately to the right of the second reticle field of FIG. 4B. As shown, the second mask 320 is moved with an offset relative to the first mask 302 such that the first overlay structure 322 is positioned further to the right relative to the pattern associated with the second box 310 of the first mask 302. The first overlay structure 322 of the second mask 320 may be positioned such that there is a third distance 406 between an edge of the first overlay structure 322 relative to an edge of the pattern associated with the second box 310. The third distance 406 is greater than the second distance 404 and the first distance 402. In this way, when exposed and processed, the first overlay structure 322 will shift the position of the first box 208 relative to the second box 210 of the die label 200 of FIG. 2 in the third reticle field, providing a position of the third reticle field on the semiconductor wafer.

FIG. 4D illustrates the stepping of the masks to a fourth reticle field immediately to the right of the third reticle field of FIG. 4B. As shown, the second mask 320 is moved with an offset relative to the first mask 302 such that the first overlay structure 322 is positioned further to the right relative to the pattern associated with the second box 310 of the first mask 302. The first overlay structure 322 of the second mask 320 may be positioned such that there is a fourth distance 408 between an edge of the first overlay structure 322 relative to an edge of the pattern associated with the second box 310. The fourth distance 406 is greater than the third distance 406, the second distance 404, and the first distance 402. In this way, when exposed and processed, the first overlay structure 322 will shift the position of the first box 208 relative to the second box 210 of the die label 200 of FIG. 2 in the third reticle field, providing a position of the fourth reticle field on the semiconductor wafer.

The example of FIGS. 4A-4D is provided in one dimension (e.g., the horizontal dimension) for purposes of illustration and discussion. The offset of the second mask relative to the first mask may be implemented in other dimensions (e.g., the vertical dimension) without deviating from the scope of the present disclosure. In some examples, the offset is implemented in both a first dimension (e.g., horizontal dimension) and a second dimension (e.g., vertical dimension) to provide a position of a reticle field in a two-dimensional grid of reticle fields on the semiconductor wafer.

Referring again to FIG. 3B, the pattern of the second overlay structure 324 mask may open, remove, or otherwise alter the square corresponding to the location of the reticle field on the semiconductor wafer. Similar to the offset of the first overlay structure 322 described with reference to FIGS. 4A-4D, the offset of the second overlay structure 324 may shift the location of the square of the two-dimensional grid that is cleared, altered, or removed from one reticle field to the next. In this way, the second overlay structure 324 may provide an indicator on the two-dimensional grid providing a location of the reticle field on the semiconductor wafer.

Other suitable patterns and overlay structures may be used to provide an offset overlay mask defined indicator in a die label providing a position of a reticle field on a semiconductor wafer without deviating from the scope of the present disclosure. For instance, in some embodiments, the indicator may include one or more lines, where the number of lines in the indicator represents the position of the reticle field on the semiconductor wafer.

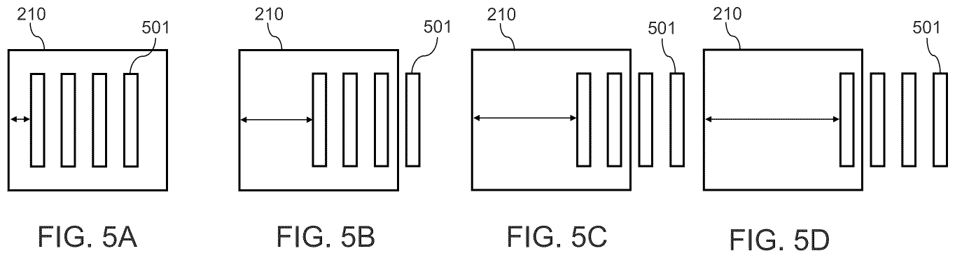

More particularly, referring to FIGS. 5A-5D, the second mask 320 of FIG. 3B may include a pattern providing an overlay structure associated with a plurality of lines 501. When exposed and processed, the second mask may provide an indicator in the die label including a number of lines within a box, such as the second box 210 of FIG. 2. As demonstrated by FIG. 5A, the lines 501 for a first reticle field are entirely within the box 210 such that when exposed and processed, the indicator would have four lines in a box providing a position of the first reticle field. In FIG. 5B, when the second mask 320 is provided with an offset relative to the first mask to expose a second reticle field, one of the lines 510 moves outside the box 210. When exposed and processed, the indicator would have three lines in a box, providing a position of the second reticle field on the semiconductor wafer. In FIG. 5C, when the second mask 320 is provided with an offset relative to the first mask to expose a third reticle field, another of the lines 510 moves outside the box 210. When exposed and processed, the indicator would have two lines in a box, providing a position of the third reticle field on the semiconductor wafer. In FIG. 5D, when the second mask 320 is provided with an offset relative to the first mask to expose a fourth reticle field, another of the lines 510 moves outside the box 210. When exposed and processed, the indicator would have one line in a box, providing a position of the fourth reticle field on the semiconductor wafer.

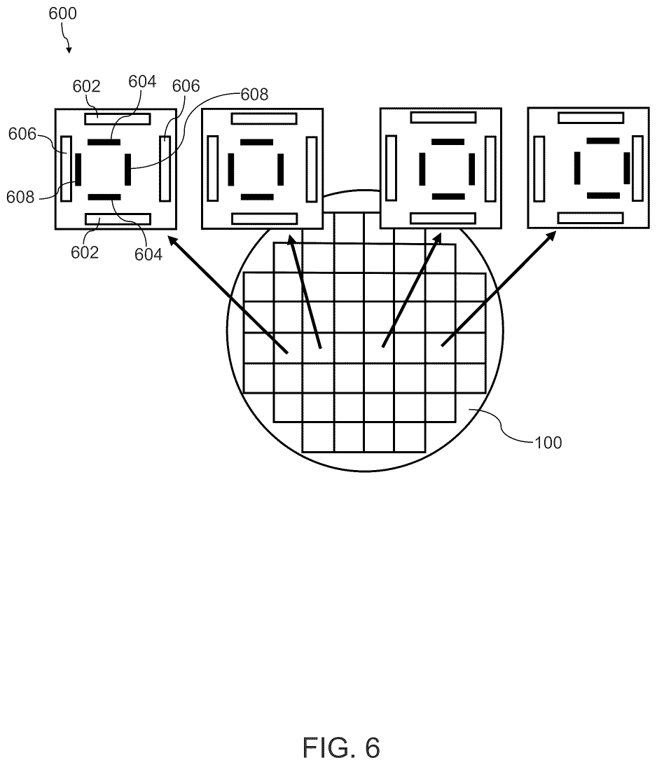

FIG. 6 depicts an offset overlay mask defined indicator 600 that provides a visual indicator of the location of the reticle field on the semiconductor wafer 100, where the indicator 600 includes one or more lines. The indicator 600 may include a first set of horizontal parallel lines 602 and a second set of horizontal parallel lines 604. The second set of horizontal parallel lines 604 may be between the first set of horizontal parallel lines 602. Similarly, the indicator 600 may include a first set of vertical parallel lines 606 and a second set of vertical parallel lines 608. The second set of vertical parallel lines may be between the first set of vertical parallel lines. 606.

The indicator 600 may be an offset overlay mask defined indicator according to example aspects of the present disclosure. More particularly, the first set of horizontal parallel lines 602 and the first set of vertical parallel lines 606 may be provided using a first mask. The second set of horizontal parallel lines 604 and the second set of vertical parallel lines may be provided using a second mask. When stepping and exposing the first mask and the second mask to provide reticle fields on the semiconductor wafer, the second mask may be provided at an offset relative to the first mask. As illustrated in FIG. 6, providing the offset (e.g., in the horizontal direction) may shift the position of the second set of vertical parallel lines 608 relative to the first set of vertical parallel lines 606 for each reticle field. In this way, the indicator 600 may provide a position of the reticle field on the semiconductor wafer.

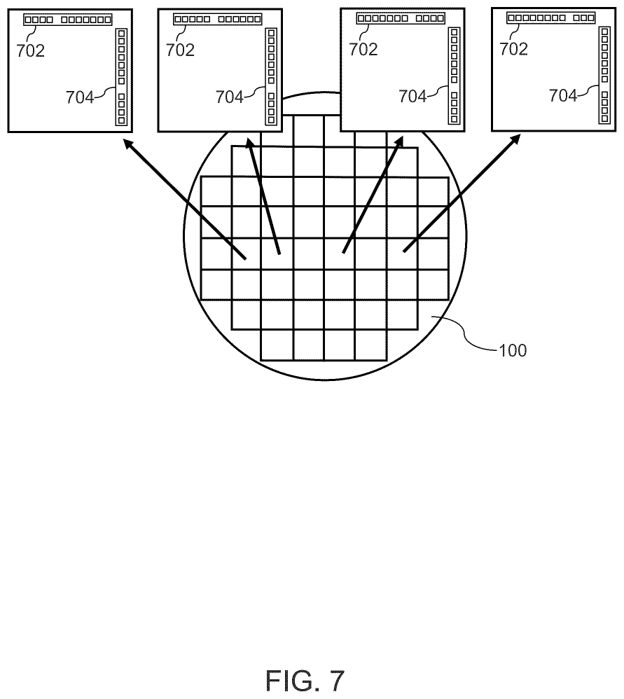

FIG. 7 depicts offset overlay mask defined indicator 700 that may be implemented as part of die label to provide a position of a reticle field on a semiconductor wafer according to example embodiments of the present disclosure. The indicator 700 may include a plurality of one-dimensional grids, such as a horizontal one-dimensional grid 702 and a vertical one dimensional grid 704. Each one-dimensional grid may include a plurality of squares indicative of a position of reticle field. For instance, the horizontal one-dimensional grid 702 may include a plurality of squares with each square indicating a horizontal position of a reticle field. The vertical one-dimensional grid 704 may include a plurality of squares with each square indicating a vertical position of the reticle field. To provide a horizontal position of a reticle field on the semiconductor wafer, one of the squares on the horizontal one-dimensional grid 702 may be cleared, marked, or altered. To provide a vertical position of a reticle field on the semiconductor wafer, one of the squares or pillars on the vertical one-dimensional grid 704 may be cleared, marked, or altered.

The indicator 700 may be an offset overlay mask defined indicator according to example aspects of the present disclosure. More particularly, the horizontal one-dimensional grid 702 and the vertical one-dimensional grid 704 may be provided using a first mask. The cleared, altered, or marked squares in the horizontal one-dimensional grid 702 and the vertical one-dimensional grid may be provided using a second mask. When stepping and exposing the first mask and the second mask to provide reticle fields on the semiconductor wafer, the second mask may be provided at an offset relative to the first mask. As illustrated in FIG. 7, providing the offset (e.g., in the horizontal direction) may shift the position of the cleared, altered or marked square. In this way, the indicator 700 may provide a position of the reticle field on the semiconductor wafer.

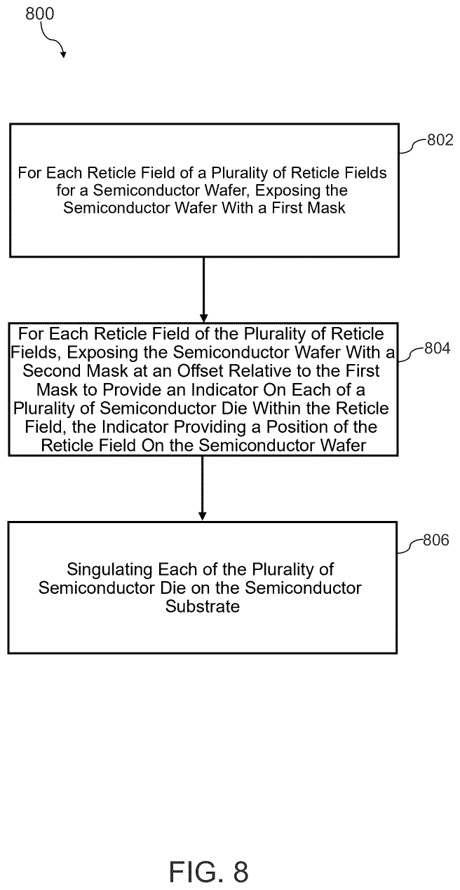

FIG. 8 depicts a flow diagram of an example method 800 according to example embodiments of the present disclosure. FIG. 8 depicts steps or operations performed in a particular order for purposes of illustration and discussion. Those of ordinary skill in the art, using the disclosures provided herein, will understand that the steps or operations of any of the methods provided herein may be adapted, expanded, include steps not illustrated, omitted, rearranged, and/or modified in various ways without deviating from the scope of the present disclosure.

At 802, the method includes for each reticle field of a plurality of reticle fields on a semiconductor wafer, exposing the semiconductor wafer with a first mask, such as the first mask 302 of FIG. 3A. In some examples, the first mask includes a first pattern associated with a die label. The first pattern may include a first portion identifying a location of a semiconductor die within one reticle field of the plurality of reticle fields. For instance, the first portion may include a pattern associated with a row identifier and a column identifier to identify the location of the semiconductor within the reticle field. The row identifier and/or the column identifier may be, for instance, an alphanumeric character.

At 804, the method includes for each reticle field of the plurality of reticle fields on a semiconductor wafer, exposing the semiconductor wafer with a second mask. The second mask may include a second pattern associated with providing an indicator as part of or as the die label to provide a position of the reticle field on the semiconductor wafer. An example second mask is the second mask 320 of FIG. 3B. The second mask may be an overlay mask relative to the first mask.

As discussed with reference to, for instance, FIGS. 4A-4D, the second mask may be exposed at an offset relative to the first mask as the second mask is scanned or stepped across the semiconductor wafer during, for instance, a photolithography process. The offset may be different for each reticle field of the plurality of reticle fields. The offset may be provided in a first dimension (e.g., horizontal dimension) and/or a second dimension (e.g., vertical dimension). In this way, exposing the second mask may provide an offset overlay mask defined indicator that provides a position of a reticle field as part of a die label according to example embodiments of the present disclosure.

At 806, the method may include, for instance, singulating each of the plurality of semiconductor die from the semiconductor wafer. Each of the plurality of semiconductor die may have a unique die label providing a position of the semiconductor die in a reticle field and providing a position of the reticle field on the semiconductor wafer. The singulated semiconductor die may be provided as part of a semiconductor device package.

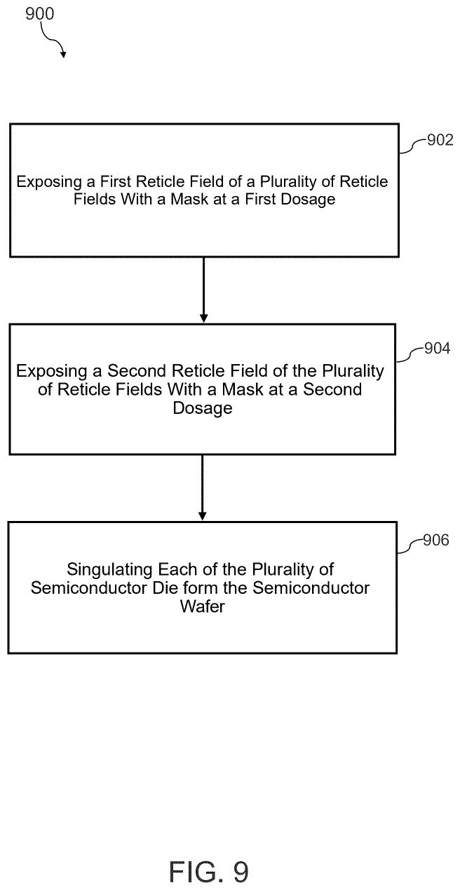

FIG. 9 depicts a flow diagram of an example method 800 according to example embodiments of the present disclosure. FIG. 9 depicts steps or operations performed in a particular order for purposes of illustration and discussion. Those of ordinary skill in the art, using the disclosures provided herein, will understand that the steps or operations of any of the methods provided herein may be adapted, expanded, include steps not illustrated, omitted, rearranged, and/or modified in various ways without deviating from the scope of the present disclosure.

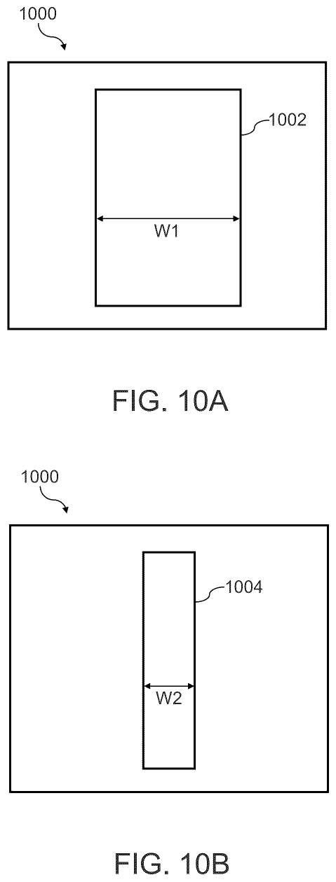

At 902, the method includes exposing a first reticle field of a plurality of reticle fields with a mask at a first dosage. For instance, FIG. 10A depicts a portion of an indicator 10000 providing a position of a reticle field on a semiconductor die according to example embodiments of the present disclosure. The indicator 1000 includes a feature 1002 transferred to the semiconductor die as a result of the exposing the first reticle field. The feature 1002 has a dimension (e.g., linewidth W1) that is dependent on the dosage of the radiation exposure of the first reticle field.

At 904, the method includes exposing a second reticle field of the plurality of reticle fields with a mask at a second dosage. The second dosage is different from the first dosage to provide an indicator on each of a plurality of semiconductor die within the reticle field. The indicator providing a position of the reticle field on the semiconductor wafer.

For instance, FIG. 10B depicts a portion of an indicator 1000 providing a position of a reticle field on a semiconductor die according to example embodiments of the present disclosure. The indicator 1000 includes a feature 1004 transferred to the semiconductor die as a result of the exposing the second reticle field. The feature 1004 has a dimension (e.g., linewidth W2) that is dependent on the dosage of the radiation exposure of the second reticle field. The linewidth W2 is a function of the second dosage that is different from the first dosage. Accordingly, the linewidth W2 is different than the linewidth W1.

FIGS. 10A and 10B depict linewidth as an example dimension of a feature affected by dosage for purposes of illustration and discussion. Other suitable features and dimensions of features may include, for instance, a spacing between lines, a number of lines transferred to be a part of the indicator, or other suitable feature.

Referring back to FIG. 9 at 906, the method may include, for instance, singulating each of the plurality of semiconductor die from the semiconductor wafer. Each of the plurality of semiconductor die may have a unique die label providing a position of the semiconductor die in a reticle field and providing a position of the reticle field on the semiconductor wafer. The singulated semiconductor die may be provided as part of a semiconductor device package.

Example aspects of the present disclosure are set forth below. Any of the below features or examples may be used in combination with any of the embodiments or features provided in the present disclosure.

One example embodiment is directed to a semiconductor die. The semiconductor die includes a semiconductor structure, the semiconductor structure including a portion of a semiconductor wafer. The semiconductor die includes a die label, the die label indicative of a fabrication position of the semiconductor die on the semiconductor wafer. The die label has a first portion identifying a location of the semiconductor die within a reticle field and a second portion identifying a location of the reticle field on the semiconductor wafer. The semiconductor wafer includes two or more reticle fields.

In one example embodiment, the first portion includes a row identifier and a column identifier to identify the location of the semiconductor die within the reticle field.

In one example embodiment, the row identifier or the column identifier includes an alphanumeric character.

In one example embodiment, the second portion provides an indicator of the location of the reticle field on the semiconductor wafer.

In one example embodiment, the indicator includes an overlay box-in-box structure.

In one example embodiment, the indicator includes a two dimensional grid.

In one example embodiment, the indicator is indicative of a total number of reticle fields on the semiconductor wafer.

In one example embodiment, the indicator includes one or more one dimensional grids.

In one example embodiment, the indicator includes one or more lines.

In one example embodiment, the reticle field is associated with a plurality of semiconductor die arranged in a semiconductor die grid.

In one example embodiment, the second portion includes an adjusted dosage defined indicator.

In one example embodiment, the second portion includes an offset overlay mask defined indicator.

In one example embodiment, the second portion does not include an alphanumeric character.

In one example embodiment, the die label includes a material provided on the semiconductor wafer.

In one example embodiment, the die label is defined by etched material from the semiconductor die.

In one example embodiment, the semiconductor wafer includes a wide bandgap semiconductor.

In one example embodiment, the semiconductor wafer includes silicon.

In one example embodiment, the semiconductor die includes one or more of a silicon carbide-based MOSFET, silicon carbide-based Schottky diode, or silicon carbide-based IGBT.

One example embodiment is directed to a method of providing a die label as part of each of a plurality of semiconductor die. The method includes, for each reticle field of a plurality of reticle fields for a semiconductor wafer, exposing the semiconductor wafer with a first mask. The method includes, for each reticle field of the plurality of reticle fields, exposing the semiconductor wafer with a second mask at an offset relative to the first mask to provide an indicator on each of a plurality of semiconductor die within the reticle field, the indicator providing a position of the reticle field on the semiconductor wafer.

In one example embodiment, the offset is different for each reticle field of the plurality of reticle fields.

In one example embodiment, the offset includes a first offset in a first dimension and a second offset in a second dimension.

In one example embodiment, the first mask includes a first pattern associated with a die label, the first pattern including a first portion identifying a location of each semiconductor die within one reticle field of the plurality of reticle fields.

In one example embodiment, the first portion includes a row identifier and a column identifier to identify the location of the semiconductor die within the reticle field.

In one example embodiment, the row identifier or the column identifier includes an alphanumeric character.

In one example embodiment, the second mask includes a second pattern associated with a die label, the second pattern including a second portion to provide the indicator provide a position of the reticle field on the semiconductor wafer.

In one example embodiment, the second mask is an overlay mask relative to the first mask.

In one example embodiment, the indicator includes an overlay box-in-box structure.

In one example embodiment, the indicator includes a two-dimensional grid.

In one example embodiment, the indicator is indicative of a total number of reticle fields on the semiconductor wafer.

In one example embodiment, the indicator includes one or more one dimensional grids.

In one example embodiment, the indicator includes one or more lines.

In one example embodiment, each reticle field is associated with a plurality of semiconductor die arranged in a semiconductor die grid.

In one example embodiment, the second mask is the same mask structure as the first mask.

In one example embodiment, the indicator does not include an alphanumeric character.

In one example embodiment, the indicator includes a material deposited on the semiconductor wafer.

In one example embodiment, the indicator is defined by etched material from the semiconductor wafer.

In one example embodiment, the indicator is an offset overlay mask defined indicator

In one example embodiment, the semiconductor wafer includes a wide bandgap semiconductor.

In one example embodiment, the semiconductor wafer includes silicon.

In one example embodiment, the semiconductor die includes one or more of a silicon carbide-based MOSFET, silicon carbide-based Schottky diode, or silicon carbide-based IGBT.

In one example embodiment, the method further includes singulating each of the plurality of semiconductor die on the semiconductor wafer.

One example embodiment is directed to a semiconductor wafer. The semiconductor wafer includes a plurality of semiconductor die, the plurality of semiconductor die arranged in a plurality of reticle fields on the semiconductor wafer, each reticle field associated with an exposure of a mask on the semiconductor wafer. Each of the plurality of semiconductor die includes a unique die label, and the unique die label includes an indicator indicative of a position of one of the plurality of reticle fields on the semiconductor wafer.

In one example embodiment, the indicator includes an overlay box-in-box structure.

In one example embodiment, the indicator includes a two dimensional grid.

In one example embodiment, the indicator is indicative of a total number of reticle field on the semiconductor wafer.

In one example embodiment, the indicator includes one or more one dimensional grids.

In one example embodiment, the indicator includes one or more lines.

In one example embodiment, the unique die label includes a portion identifying a location of the semiconductor die within one reticle field of the plurality of reticle fields.

In one example embodiment, the portion identifying a location of the semiconductor die within one reticle field of the plurality of reticle fields includes a row identifier and a column identifier to identify the location of the semiconductor die within the one reticle field of the plurality of reticle fields.

In one example embodiment, the row identifier or the column identifier includes an alphanumeric character.

In one example embodiment, each reticle field is associated with a plurality of semiconductor die arranged in a semiconductor die grid.

In one example embodiment, the indicator is an overlay offset mask defined indicator or an adjusted dosage defined indicator.

In one example embodiment, the indicator does not include an alphanumeric character.

In one example embodiment, the indicator includes a material deposited on the semiconductor wafer.

In one example embodiment, the indicator is defined by etched material from the semiconductor wafer.

In one example embodiment, the unique die label is different for each of the plurality of semiconductor die on the semiconductor wafer.

In one example embodiment, the semiconductor wafer includes a wide bandgap semiconductor.

In one example embodiment, the semiconductor wafer includes silicon.

In one example embodiment, the plurality of semiconductor die each include one or more of a silicon carbide-based MOSFET, silicon carbide-based Schottky diode, or silicon carbide-based IGBT.

One example embodiment is directed to a method of providing a die label as part of each of a plurality of semiconductor die on a semiconductor wafer. The method includes exposing a first reticle field of a plurality of reticle fields with a mask at a first dosage. The method includes exposing a second reticle field of the plurality of reticle fields with a mask at a second dosage, the second dosage being different from the first dosage to provide an indicator on each of a plurality of semiconductor die within the reticle field, the indicator providing a position of the reticle field on the semiconductor wafer.

In one example embodiment, the indicator includes a feature having a first dimension in the first reticle and a second dimension in the second reticle.

In one example embodiment, the feature is a linewidth.

In one example embodiment, the feature is a spacing between lines.

In one example embodiment, the feature is a number of lines.

In one example embodiment, the method further includes singulating each of the plurality of semiconductor die from the semiconductor wafer.

In one example embodiment, the semiconductor wafer includes a wide bandgap semiconductor.

In one example embodiment, the semiconductor wafer includes silicon.

In one example embodiment, the semiconductor die includes one or more of a silicon carbide-based MOSFET, silicon carbide-based Schottky diode, or silicon carbide-based IGBT.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A semiconductor die, comprising:
a semiconductor structure, the semiconductor structure comprising a portion of a semiconductor wafer;
wherein the semiconductor die comprises a die label, the die label indicative of a fabrication position of the semiconductor die on the semiconductor wafer; and
wherein the die label has a first portion identifying a location of the semiconductor die within a reticle field and a second portion identifying a location of the reticle field on the semiconductor wafer, wherein the semiconductor wafer comprises two or more reticle fields.

2. The semiconductor die of claim 1, wherein the first portion comprises a row identifier and a column identifier to identify the location of the semiconductor die within the reticle field.

3. The semiconductor die of claim 2, wherein the row identifier or the column identifier comprises an alphanumeric character.

4. The semiconductor die of claim 1, wherein the second portion provides an indicator of the location of the reticle field on the semiconductor wafer.

5. The semiconductor die of claim 4, wherein the indicator comprises an overlay box-in-box structure.

6. The semiconductor die of claim 4, wherein the indicator comprises a two dimensional grid.

7. The semiconductor die of claim 6, wherein the indicator is indicative of a total number of reticle fields on the semiconductor wafer.

8. The semiconductor die of claim 4, wherein the indicator comprises one or more one dimensional grids.

9. The semiconductor die of claim 4, wherein the indicator comprises one or more lines.

10. The semiconductor die of claim 1, wherein the reticle field is associated with a plurality of semiconductor die arranged in a semiconductor die grid.

11. The semiconductor die of claim 1, wherein the second portion comprises an adjusted dosage defined indicator.

12. The semiconductor die of claim 1, wherein the second portion comprises an offset overlay mask defined indicator.

13. The semiconductor die of claim 1, wherein the second portion does not comprise an alphanumeric character.

14. The semiconductor die of claim 1, wherein the die label comprises a material provided on the semiconductor wafer.

15. The semiconductor die of claim 1, wherein the die label is defined by etched material from the semiconductor die.

16. The semiconductor die of claim 1, wherein the semiconductor wafer comprises a wide bandgap semiconductor.

17. The semiconductor die of claim 1, wherein the semiconductor wafer comprises silicon.

18. The semiconductor die of claim 1, wherein the semiconductor die comprises one or more of a silicon carbide-based MOSFET, silicon carbide-based Schottky diode, or silicon carbide-based IGBT.

19. A method of providing a die label as part of each of a plurality of semiconductor die, the method comprising:
for each reticle field of a plurality of reticle fields for a semiconductor wafer, exposing the semiconductor wafer with a first mask,
for each reticle field of the plurality of reticle fields, exposing the semiconductor wafer with a second mask at an offset relative to the first mask to provide an indicator on each of a plurality of semiconductor die within the reticle field, the indicator providing a position of the reticle field on the semiconductor wafer.

20. A semiconductor wafer, comprising:
a plurality of semiconductor die, the plurality of semiconductor die arranged in a plurality of reticle fields on the semiconductor wafer, each reticle field associated with an exposure of a mask on the semiconductor wafer; and
wherein each of the plurality of semiconductor die comprises a unique die label, wherein the unique die label comprises an indicator indicative of a position of one of the plurality of reticle fields on the semiconductor wafer.
